(19) United States
(12) Patent Application Publication
(10) Pub. No.: US 2012/0257473 A1
(43) Pub. Date: Oct. 11, 2012

(54) METHOD FOR OPERATING AN ELECTROMECHANICAL TRANSDUCER SYSTEM AND ELECTROMECHANICAL TRANSDUCER SYSTEM

(75) Inventors: Martin Rzehorska, Peggau (AT); Jerome Gruaz, Graz (AT); Klaus-Christoph Harms, Thal/Graz (AT); Rüdiger Teichmann, Hart B. Graz (AT)

(73) Assignee: AVL LIST GMBH

(21) Appl. No.: 13/503,044

(22) PCT Filed: Oct. 20, 2010
(86) PCT No.: PCT/EP10/65817

§ 371 Date: Jun. 7, 2012

(30) Foreign Application Priority Data
Oct. 22, 2009 (AT) GM 668/2009

(51) Int. Cl. G01R 31/28

(52) U.S. Cl. 367/13

(57) ABSTRACT

For operating an electromechanical transducer system with at least one piezoelectric transducer element, if necessary at least one identification element and an electronic control unit, on the one hand, the wanted signals of a certain utility operating range defined by the frequency band and time window thereof, assigned to at least one piezoelectric transducer element, as well as, on the other hand, inquiry signals and response signals for the functional testing of the transducer system are transmitted via a line system with only one electrical signal line.

In order to thereby render possible a simple and reliable diagnosis method for the input circuit of cable break, with a corresponding increase in operational reliability, reduction of error search times and simplification of operation, at least one inquiry signal located outside the utility operating range of the transducer element is transmitted to the transducer system and from the resulting response signal at least one characteristic value is formed and at least one previously determined criterion is queried, wherein in the event of non-fulfillment of the criterion, an error message is generated.

The invention relates to a method for operating an electromechanical transducer system with at least one piezoelectric transducer element, at least one identification element and an electronic control unit, wherein, on the one hand, the wanted signals of a certain utility operating range defined by the frequency band and time window thereof, assigned to at least one piezoelectric transducer element, as well as, on the other hand, inquiry signals and response signals for the functional testing of the transducer system are transmitted via a line system with only one electrical signal line, as well as an electromechanical transducer system, comprising at least one piezoelectric transducer element, in addition at least one identification element, and a line system with only one electrical signal line for transmitting, on the one hand, the wanted signals of a certain utility operating range defined by the frequency band and time window thereof, assigned to at least one piezoelectric transducer element, as well as, on the other hand, inquiry signals and response signals for the functional testing of the transducer system, as well as an electronic control unit.

In principle it is known for the testing or monitoring of the current state of a cable connection from and to sensors to carry out delay time measurements, which is complex, however, due to the necessity of measurement and evaluation apparatus in this respect. This applies all the more if cables of different lengths are used.

In the case of piezoelectric sensors—together with cable and plug connector—a cable break detection is very difficult to establish due to the required high insulation at the input of the charge amplifier. In EP 423 273 B1 an arrangement is described in which changes to the resonant frequency of piezoelectric elements were drawn on as indications of the operational capability of the entire measuring chain, from the sensor via the cable, etc. to the amplifier.

IN U.S. Pat. No. 5,821,425 a SAW element provided with a type of predetermined breaking point between the input and output transducer is described as a break sensor. If a structure connected to a sensor of this type is mechanically damaged, an output signal can no longer be received, which then can be used as an indication of structural damage, but not of the operational capability of the measuring chain.

The object of the present invention is therefore a simple and reliable diagnosis method for the input circuit of cable break, with a corresponding increase in operational reliability, reduction of error search times and simplification of operation.

To attain this object, the method described at the outset is characterized in that at least one inquiry signal located outside the utility operating range of the transducer element is transmitted to the transducer system and from the resulting response signal at least one characteristic value is formed and at least one previously determined criterion is queried, wherein in the event of non-fulfillment of the criterion, an error message is generated. The functional monitoring and the measuring signal transmission can thus be separated well and both operations can take place uninfluenced by one another, if necessary at the same time or overlapping.

According to a first embodiment variant of the method according to the invention, it is provided that in a phase with ensured state and error-free function of the transducer system at least one inquiry signal is transmitted to the transducer and from the resulting response signal at least one reference characteristic value is formed and saved, wherein the adequate conformity in the operating phase of the respectively current characteristic value currently formed from the response signal with this reference value is used as criterion.

If according to a further embodiment variant of the method at least one inquiry signal is already transmitted before the first transmission of a wanted signal, it can thus be ensured that the intended operation takes place only when the transducer is correctly coupled and functional.

In a method variant in which an inquiry signal is transmitted at least once during the operating phase as intended of the transducer system, the proper operation can thus be monitored.

Advantageously, it is provided that the repetition frequency of the inquiry signals lies in the zero frequency band of the transducer.

According to an advantageous variant, it is provided that the identification element operates purely passively and high-frequency inquiry signals are used. Advantageously, the coupling of the inquiry unit thereby takes place in an inductive manner, but capacitive coupling or antenna coupling is also possible. The high frequency of the inquiry signal (typically in the range of more than 400 MHz) thereby permits an efficient coupling, in particular in the case of inductive coupling, without interaction with wanted signal and resonant frequencies of the transducer element.

If the characteristic value formed from the response signal comprises the data of the identification signal contained in the response signal, at the same time as the functional monitoring a unique assignment of the transducer system in the overall arrangement can be made.

A particularly simple embodiment variant of the method provides that one of the electric variables current or voltage is applied with a constant value different from zero as an inquiry signal to the transducer system, that the respectively other of the two variables is detected as a resulting response signal, wherein the criterion for the error message is a previously determined limit value for a characteristic value of the detected variable.

According to a further embodiment, it can be provided that an integral value, proportional to the charge quantity, of a current detected as a response signal is used as a characteristic value.

The integral value reached during the duration of the inquiry signal can also be used as a characteristic value.

Alternatively thereto, the integration duration until a predetermined integral value is reached can be used as a criterion characteristic value.

A further variant of the method according to the invention is characterized in that the increase rate of an integral value, proportional to the charge quantity, of a current detected as a response signal is used as characteristic value.

The increase in voltage can also be detected as the characteristic value of the response signal.

Another variant according to the invention of the method provides that a current permanently applied to the transducer system anyway is used as an inquiry signal, wherein the deviation of a voltage resulting therefrom from a constant voltage is used in the electronic control unit as a control variable for the current strength, and this control variable is used as a criterion.

Advantageously, the current applied permanently to the transducer system for the drift compensation of a charge amplifier can thereby be used as an inquiry signal and a control signal controlling the current generation can be used as a criterion.

To attain the set object, the transducer system described at the outset is characterized according to the invention in that the inquiry signals are located outside the utility operating range of the transducer element and that a module is implemented in the electronic control unit which forms at least one characteristic value from the response signal and generates an error message in the event of non-fulfillment of a criterion previously stipulated.

Advantageously, it is provided thereby that the repetition frequency of the inquiry signals lies in the zero frequency range of the transducer.

A further advantageous embodiment of the invention provides that the identification element operates purely passively and the inquiry unit generates an inquiry signal with high frequency. A high-frequency inquiry signal of this type, typically in the range of more than 400 MHz, renders possible in particular an effective inductive coupling to the transducer element without interaction with wanted signal and resonant frequencies of the transducer element. With other embodiments, units for capacitive coupling or antenna coupling would also be possible.

Advantageously, a reference characteristic value obtained from the data of the identification element is stored as a criterion. A unique characteristic value can thus be connected to the unique identification of the transducer system in the overall system.

According to an advantageous embodiment of the invention, the transducer system is characterized in that a device is provided with which one of the electric variables current or voltage is applied with a constant value different from zero as an inquiry signal to the transducer system, and that a further device is provided, with which the respectively other of the two values is detected as a resulting response signal, wherein a previously determined limit value for a characteristic value of the detected variable is stored as a criterion for the error message.

Thereby a device for determining an integral value, proportional to the charge quantity, of a current detected as a response signal can be provided for use as characteristic value.

Advantageously, the device for determining the integral value reached during the duration of the inquiry signal is designed as a characteristic value.

Otherwise, it could also be provided that the device for determining the integration duration until a predetermined integral value is reached is designed as characteristic value.

An embodiment would also be conceivable in which the device is designed for determining the increase rate of an integral value, proportional to the charge quantity, of a current detected as a response signal.

Another embodiment of the invention that is easy to realize is characterized in that a device for determining the voltage increase is provided as a characteristic value.

According to another embodiment, a device can also be provided, with which a current is permanently applied to the transducer system and the deviation of a voltage resulting therefrom from a constant voltage is used as control variable for the current strength and that this control variable is used as a criterion in the module.

An advantageous embodiment of the invention using tested components that are usually present anyway is finally characterized in that a device for the drift compensation of a charge amplifier is provided, the current thereof permanently applied to the transducer system is used as an inquiry signal and that the control signal controlling the current generation is used as a criterion in the module.

In the following description the invention is explained in greater detail based on exemplary embodiments with reference to the attached drawings.

FIG. 1 thereby shows very diagrammatically the simplest arrangement according to the invention,

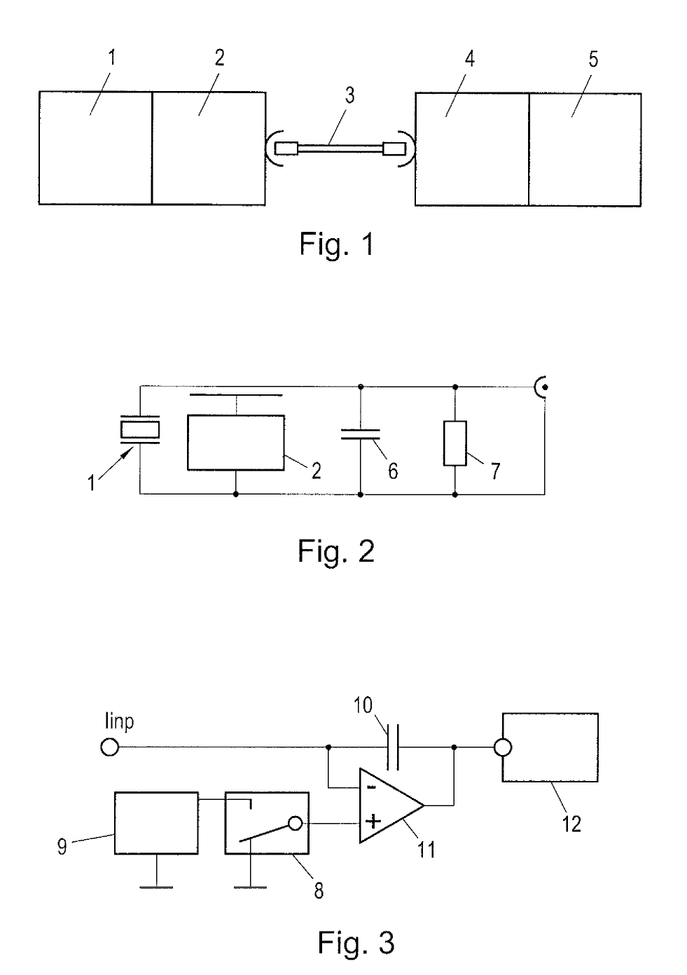

FIG. 2 shows a circuit diagram of an electromagnetic transducer element according to the invention,

FIG. 3 is a circuit diagram of a circuit for carrying out the method according to the invention on the basis of the current-voltage correlation,

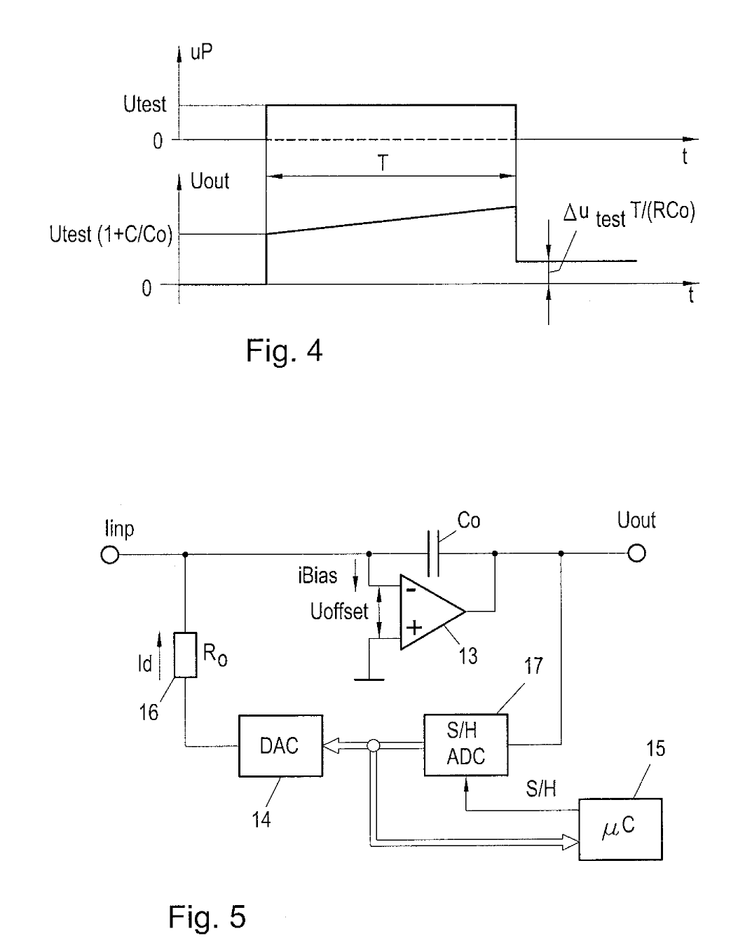

FIG. 4 is a diagram of the voltage curves occurring during an inquiry with the device of FIG. 3, and

FIG. 5 is a circuit diagram of a circuit that is expanded compared to FIG. 3 for carrying out the method according to the invention on the basis of the current-voltage correlation.

The electromechanical transducer system sketched in FIG. 1 is composed of at least one piezoelectric transducer system 1, which preferably can be provided with in addition at least one identification element 2.

This arrangement of transducer element 1 and identification element 2 is connected to an inquiry unit 4 for the identification element 2 and an operational unit 5 for operating the transducer element 1 via a line system with only one electrical signal line 3. The wanted signals assigned to the piezoelectric transducer element 1 as well as the inquiry and response signals for functional testing of the transducer system are transmitted via the line 3. Furthermore, an additional electronic control unit, which is not shown here, can be provided.

Each piezoelectric transducer system 1 has a certain utility operating range defined by a frequency band and time window. In order by the functional testing of the transducer system 1 now not to influence the intended operation thereof, the inquiry signals of the inquiry unit 4 are located outside the utility operating range of the transducer element 1. The inquiry signal or the response signal can thereby have a much higher frequency, e.g., several decimal powers higher, than a regular measuring signal, whereby it is very easy to distinguish between inquiry signal or response signal and measuring signal. Typically, the inquiry signals for transducer elements 1 in the form of piezoelectric sensors are in the range of more than 400 MHz.

The response signal to the inquiry signals is evaluated in a module that can be implemented in the electronic control unit or also already in the inquiry unit 4 itself, wherein this evaluation comprises the formation of at least one characteristic value from the inquiry signal. If this characteristic value does not fulfill a previously determined criterion stored in the module, an error message is generated.

A piezoelectric transducer system 1 can be, for example, a piezoelectric pressure sensor in an arrangement for measurement data acquisition, which is connected via measurement sensor lines to a suitable measuring amplifier. The measuring amplifier can thereby be a separate device that is connected via measuring signal lines 3 to a measurement data evaluation unit 5, e.g., an index device or a test stand control. The measuring signal line 3 of the sensor 1 is simultaneously also an inquiry line for this sensor.

The inquiry unit 4 can advantageously be connected to the measuring data evaluation unit 5 or integrated therein. The inquiry signal going via the common measuring signal/inquiry line 3 is recorded and processed by the measuring amplifier of the piezoelectric pressure sensor of the transducer system 1 in that, for example, in succession a corresponding response signal is transmitted, e.g., as a pulse, pulse train or in a digital data transmission or as a signal of a certain frequency, etc. The response signal is thereby advantageously different from the measuring signals in order to render possible an easy recognition. If no response signal arrives at the inquiry unit 4 of the measurement data evaluation unit, it can be assumed that the cabling between the input of the measurement data evaluation unit and the associated measuring amplifier of the pressure sensor is faulty or not available, e.g., due to a faulty cable or a cable not plugged or incorrectly plugged. A possible cabling error can thus be limited to a small unit. The connection quality can also be tested by means of the evaluation of the signal quality of the response signal, which also permits a diagnosis of the cabling.

As can be seen from FIG. 2 with a circuit diagram of the arrangement of transducer element 1 and identification element 2, as identification element 2, for example, can be embodied as a SAW tag, and thus operate purely passively. The inquiry signal generated by the inquiry unit 4 can thus be ideally inductively coupled at high frequency—compared to the wanted signals of the transducer element 1. Typically, the frequencies of the inquiry signals for piezoelectric sensor systems are in the range of more than 400 MHz. On the other hand, however, a capacitive coupling can also be provided, or also an antenna coupling. The capacity or the ohmic resistance of the arrangement of transducer 1 and identification element 2 are represented in the circuit diagram by the capacity 6 and the resistance 7 respectively.

This identification of the transducer system 1, which can also be integrated in measurement amplifiers of sensors, for example, can be used for testing the configuration of a measurement arrangement or for the automatic detection of this configuration. For example, if no response signal arrives at an input of the measurement data evaluation unit provided according to the stored configuration, or if this signal arrives at an incorrect input, a cabling error or a faulty cable can be present. Through individual inquiry of the transducer system 1 and checking at which channel of a multichannel measurement data evaluation unit a specific response comes back, the configuration can be detected and e.g. transferred to management software. The operating staff can also be helped with the cabling in that e.g. during the cabling it is continuously tested whether the plugged cables also correspond to the provided configuration.

In FIG. 3 a method is explained by means of a circuit diagram in which a current Iinp is applied with a constant value different from zero as an inquiry signal to the transducer system 1, 2. As a resulting response signal, the resulting voltage Uout is then detected, wherein the criterion for the error message is a previously determined limit value for a characteristic value of the detected variable voltage. In the example shown, the voltage increase is detected as the relevant characteristic value of the response signal, the course of which voltage increase is shown in FIG. 4.

In normal measurement operation, the switch 8 in FIG. 3 is in the “operate” position. For a query, the switch is placed in the “test” position and thus a test voltage Utest is applied via a voltage source 9 to the non-inverting input of the operation amplifier 11 switched parallel to the condenser 10. The voltage curves shown in FIG. 4 result thereby, wherein any line break can then be recognized from the course of the output voltage Uout.

A further exemplary embodiment for concluding in the application of a test voltage a possible line break from the resulting output signal is shown in FIG. 5. An inquiry current Iinp is permanently applied to the transducer system 1, 2 including cable 3, and the resulting voltage at the input of the charge amplifier 12 is compared to the low offset voltage Uoffset, virtually always present, which is different from zero. In contrast to FIG. 3, here a test voltage is not fed to the non-inverting input of the operation amplifier 12, but generated by means of a digital-analog converter 13, controlled via the microprocessor 14 and fed as test current Id via the resistance 15 to the inverting input of the operation amplifier 12. Any small deviation is here amplified as it were endlessly, detected at certain times by an analog-digital converter with sample&hold element 15 and the microprocessor 14 and used as control variable for the generation of the inquiry current.

The microprocessor 14 is moreover used to evaluate the output voltage Uout caused by the test voltage and to detect a possible cable break. To this end a digital line is provided from the analog-digital converter with sample&hold element 15 to the microcomputer 14 in order to query this control variable. If this control variable exceeds a value predetermined as a criterion, then either the bias current or the stray current (Uoffset/Risolation) is too large.

1. A method for operating an electromechanical transducer system with at least one piezoelectric transducer element, at least one identification element and an electronic control unit, wherein, on the one hand, the wanted signals of a certain utility operating range defined by the frequency band and time window thereof, assigned to at least one piezoelectric transducer element, as well as, on the other hand, inquiry signals and response signals for the functional testing of the transducer system are transmitted via a line system with only one electrical signal line, wherein at least one inquiry signal located outside the utility operating range of the transducer element is transmitted to the transducer system and from the resulting response signal at least one characteristic value is formed and at least one previously determined criterion is queried, wherein in the event of non-fulfillment of the criterion, an error message is generated.

2. The method according to claim 1, wherein in a phase with ensured state and error-free function of the transducer system at least one inquiry signal is transmitted to the transducer and from the resulting response signal at least one reference characteristic value is formed and saved, wherein the adequate conformity in the operating phase of the respectively current characteristic value currently formed from the response signal with this reference value is used as criterion.

3. The method according to claim 2, wherein at least one inquiry signal is already transmitted before the first transmission of a wanted signal.

4. The method according to claim 3, wherein an inquiry signal is transmitted at least once during the operating phase as intended of the transducer system.

5. The method according to claim 4, wherein the repetition frequency of the inquiry signals lies in the zero frequency band of the transducer.

6. The method according to claim 5, wherein the identification element operates purely passively and high-frequency inquiry signals are used.

7. The method according to claim 6, wherein the characteristic value formed from the response signal comprises the data of the identification signal contained in the response signal.

8. The method according to claim 5, wherein one of the electric variables current or voltage is applied with a constant value different from zero as an inquiry signal to the transducer system, that the respectively other of the two variables is detected as a resulting response signal, wherein the criterion for the error message is a previously determined limit value for a characteristic value of the detected variable.

9. The method according to claim 8, wherein an integral value, proportional to the charge quantity, of a current detected as a response signal is used as a characteristic value.

10. The method according to claim 9, wherein the integral value reached during the duration of the inquiry signal is used as a characteristic value.

11. The method according to claim 9, wherein the integration duration until a predetermined integral value is reached is used as a criterion characteristic value.

12. The method according to claim 8, wherein the increase rate of an integral value, proportional to the charge quantity, of a current detected as a response signal is used as characteristic value.

13. The method according to claim 8, wherein the increase in voltage is detected as the characteristic value of the response signal.

14. The method according to claim 6, wherein a current permanently applied to the transducer system anyway is used as an inquiry signal, wherein the deviation of a voltage resulting therefrom from a constant voltage is used in the electronic control unit as a control variable for the current strength, and this control variable is used as a criterion.

15. The method according to claim 14, wherein the current applied permanently to the transducer system for the drift compensation of a charge amplifier is used as an inquiry signal and a control signal controlling the current generation is used as a criterion.

16. An electromechanical transducer system, comprising at least one piezoelectric transducer element (1), in addition at least one identification element (2), and a line system with only one electrical signal line (3) for transmitting, on the one hand, the wanted signals of a certain utility operating range defined by the frequency band and time window thereof, assigned to at least one piezoelectric transducer element (1), as well as, on the other hand, inquiry signals and response signals for the functional testing of the transducer system (1, 2, 3), as well as an electronic control unit (4, 5), wherein the inquiry signals are located outside the utility operating range of the transducer element (1) and that a module (4) is implemented in the electronic control unit (4, 5) which forms at least one characteristic value from the response signal and generates an error message in the event of non-fulfillment of a criterion previously stipulated.

17. The transducer system according to claim 16, wherein the repetition frequency of the inquiry signals lies in the zero frequency band of the transducer (1).

18. The transducer system according to claim 16, wherein the identification element (2) operates purely passively and the inquiry unit (4) generates an inquiry signal with high frequency.

19. The transducer system according to claim 18, wherein a reference characteristic value obtained from the data of the identification element (2) is stored as a criterion.

20. The transducer system according to claim 19, wherein a device is provided with which one of the electric variables current or voltage is applied with a constant value different from zero as an inquiry signal to the transducer system (1, 2, 3), and that a further device is provided, with which the respectively other of the two values is detected as a resulting response signal, wherein a previously determined limit value for a characteristic value of the detected variable is stored as a criterion for the error message.

21. The transducer system according to claim 20, wherein a device for determining an integral value, proportional to the charge quantity, of a current detected as a response signal is provided for use as characteristic value.

22. The transducer system according to claim 21, wherein the device for determining the integral value reached during the duration of the inquiry signal is designed as a characteristic value.

23. The transducer system according to claim 21, wherein the device for determining the integration duration until a predetermined integral value is reached is designed as characteristic value.

24. The transducer system according to claim 21, wherein the device is designed for determining the increase rate of an integral value, proportional to the charge quantity, of a current detected as a response signal.

25. The transducer system according to claim 20, wherein a device for determining the voltage increase is provided as a characteristic value.

26. The transducer system according to claim 20, wherein a device (8, 9) is provided, with which a current is permanently applied to the transducer system (1, 2, 3) and the deviation of a voltage resulting therefrom from a constant voltage is used as control variable for the current strength and that this control variable is used as a criterion in the module.

27. The transducer system according to claim 21, wherein a device (13, 14, 15) for the drift compensation of a charge amplifier (12) is provided, the current thereof permanently applied to the transducer system (1, 2, 3) is used as an inquiry signal and that the control signal controlling the current generation is used as a criterion in the module.
